(19) United States
(12) Patent Application Publication
(10) Pub. No.: US 2026/0068575 A1
(43) Pub. Date: Mar. 5, 2026

(54) MANUFACTURING METHOD

(71) Applicant: DISCO CORPORATION, Tokyo (JP)

(72) Inventors: Naoko Yamamoto, Tokyo (JP); Shunsuke Teranishi, Tokyo (JP)

(21) Appl. No.: 19/311,413

(22) Filed: Aug. 27, 2025

(30) Foreign Application Priority Data
Sep. 4, 2024 (JP) 2024-152340

(51) Int. Cl. H01L 21/78; H01L 21/463; H01L 21/683

(52) U.S. Cl. CPC H01L 21/78

(57) ABSTRACT

A method is of manufacturing a plurality of devices by dividing a device wafer along a plurality of planned dividing lines intersecting each other, the device wafer having a device surface on which each of the devices is formed in each of regions partitioned by the planned dividing lines. The method includes: directly bonding a carrier plate to the device surface of the device wafer; after the bonding of the carrier plate, dicing the device wafer supported by the carrier plate along the planned dividing lines to thereby form a plurality of devices; and after the forming of the plurality of devices, separating the plurality of devices from the carrier plate.

### CROSS-REFERENCE TO RELATED APPLICATION(S)

The present application claims priority to and incorporates by reference the entire contents of Japanese Patent Application No. 2024-152340 filed in Japan on Sep. 4, 2024.

### BACKGROUND

The present disclosure relates to a manufacturing method of manufacturing a plurality of devices.

In recent years, hybrid bonding in which electrodes on the surface of a device wafer are connected to each other has started to be adopted in accordance with high integration of devices.

In hybrid bonding, since the surfaces of device wafers are bonded to each other, a bonding failure may occur if foreign matters adhere to the surfaces of the wafers.

For this reason, in hybrid bonding, it is strongly desired to reduce the adhesion of foreign matters to the surface of the device wafer after dicing as compared with the conventional bonding via bumps.

Therefore, there is disclosed a method of dicing a wafer while protecting the wafer with a protective sheet (e.g., see JP 2005-175148 A).

However, the method disclosed in JP 2005-175148 A has a problem that a residue of an adhesive remains on a protective sheet on which an adhesive layer is formed.

### SUMMARY

A method according to one aspect of the present disclosure is of manufacturing a plurality of devices by dividing a device wafer along a plurality of planned dividing lines intersecting each other, the device wafer having a device surface on which each of the devices is formed in each of regions partitioned by the planned dividing lines. The method includes: directly bonding a carrier plate to the device surface of the device wafer; after the bonding of the carrier plate, dicing the device wafer supported by the carrier plate along the planned dividing lines to thereby form a plurality of devices; and after the forming of the plurality of devices, separating the plurality of devices from the carrier plate.

### BRIEF DESCRIPTION OF THE DRAWINGS

FIG. 1 is a perspective view schematically illustrating a device wafer to be processed by a manufacturing method according to a first embodiment;

FIG. 2 is a flowchart illustrating a flow of the manufacturing method according to the first embodiment;

FIG. 3 is a perspective view schematically illustrating a carrier plate to be subjected to a hydrophilic treatment in an oxide film forming step of the manufacturing method illustrated in FIG. 2;

FIG. 4 is a cross-sectional view schematically illustrating a carrier plate that has been subjected to a hydrophilic treatment in the oxide film forming step of the manufacturing method illustrated in FIG. 2;

FIG. 5 is a cross-sectional view schematically illustrating a device wafer that has been subjected to a hydrophilic treatment in the oxide film forming step of the manufacturing method illustrated in FIG. 2;

FIG. 6 is a side view schematically illustrating, partly in cross section, a trimming step of the manufacturing method illustrated in FIG. 2;

FIG. 7 is a cross-sectional view schematically illustrating the device wafer and the like after a bonding step of the manufacturing method illustrated in FIG. 2;

FIG. 8 is a side view schematically illustrating, partly in cross section, a grinding step of the manufacturing method illustrated in FIG. 2;

FIG. 9 is a side view schematically illustrating, partly in cross section, a state in which the device wafer held on a chuck table is imaged in a dividing step of the manufacturing method illustrated in FIG. 2;

FIG. 10 is a side view schematically illustrating, partly in cross section, a state in which the device wafer is cut in the dividing step of the manufacturing method illustrated in FIG. 2;

FIG. 11 is a cross-sectional view schematically illustrating a state in which a dicing tape is attached to back surfaces of a plurality of device chips in a separating step of the manufacturing method illustrated in FIG. 2; and

FIG. 12 is a cross-sectional view schematically illustrating a state in which a carrier wafer is separated from front surfaces of the device chips in the separating step of the manufacturing method illustrated in FIG. 2.

### DETAILED DESCRIPTION

A mode (embodiment) for carrying out the present disclosure will be described in detail with reference to the drawings. The present invention is not limited to the contents described in the following embodiments. Further, the components described below include those which can be easily assumed by those skilled in the art, and those which are substantially the same. Further, the configurations described below can be combined as appropriate. In addition, various omissions, substitutions, or changes of the configuration can be made without departing from the gist of the present invention.

### First Embodiment

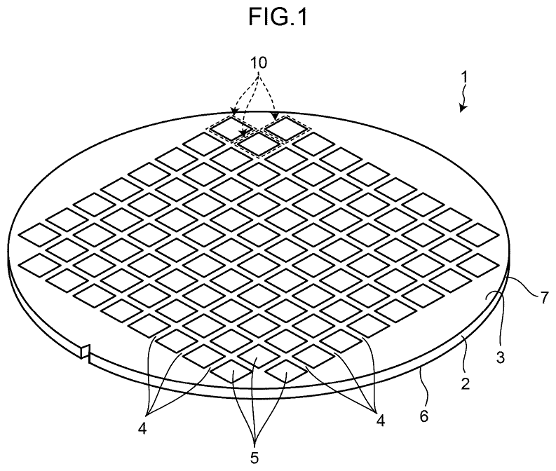

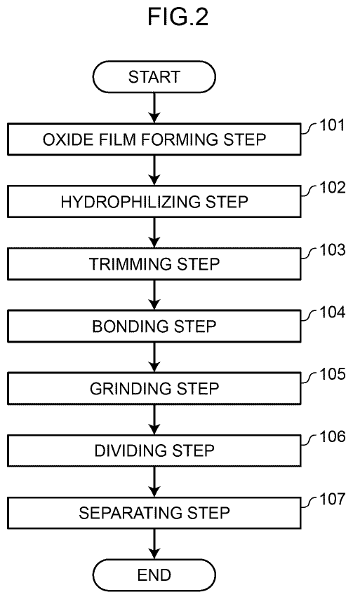

A manufacturing method according to a first embodiment of the present disclosure will be described with reference to the drawings. FIG. 1 is a perspective view schematically illustrating a device wafer to be processed by the manufacturing method according to the first embodiment. FIG. 2 is a flowchart illustrating a flow of the manufacturing method according to the first embodiment.

### Device Wafer

The manufacturing method according to the first embodiment is a method of processing a device wafer 1 illustrated in FIG. 1. As illustrated in FIG. 1, the device wafer 1 to be processed by the manufacturing method according to the first embodiment is, for example, a wafer such as a disk-shaped semiconductor wafer or an optical device wafer having a base material 2 made of silicon, sapphire, gallium, SiC, or the like.

As illustrated in FIG. 1, a device 5 is formed in each of regions partitioned in a lattice shape by a plurality of planned dividing lines 4 intersecting each other on a front surface 3 (corresponding to a device surface) of the device wafer 1. As described above, the device wafer 1 has the front surface 3, which is a device surface on which the device 5 is formed.

The device 5 is, for example, an integrated circuit such as an integrated circuit (IC) or a large scale integration (LSI), or a memory (semiconductor storage device). The device wafer 1 is divided into individual device chips 10 (corresponding to devices) along the planned dividing lines 4. Note that, in the following description, the same parts of the device wafer 1 and the device chips 10 are denoted by the same reference numerals.

In addition, in the first embodiment, the device wafer 1 is formed with TEG not illustrated on the front surface 3 of the planned dividing lines 4. The TEG is made of metal, is an element for evaluation for finding out a problem in design or manufacture occurring in the device 5, and is provided on the center in the width direction of a part of the planned dividing lines 4. Note that, in the present disclosure, the device wafer 1 may be provided with a metal on the front surface of the planned dividing lines 4 instead of the TEG. Further, in the present disclosure, the device wafer 1 may not be formed with a metal such as TEG on the front surface 3 of the planned dividing lines 4.

Further, in the first embodiment, a chamfered portion 7 is formed on the outer edge portion of the device wafer 1 over the entire circumference. The chamfered portion 7 is formed over the flat front surface 3, the outer edge of the flat front surface 3, and the outer edge of the back surface 6 on the back side of the front surface, and is formed in an arc shape in cross section so that the center in the thickness direction is located on the outermost peripheral side.

### Manufacturing Method

The manufacturing method according to the first embodiment is a method of manufacturing a plurality of device chips 10 by dividing the above-described device wafer 1 along the planned dividing lines 4. As illustrated in FIG. 2, the manufacturing method according to the first embodiment includes an oxide film forming step 101, a hydrophilizing step 102, a trimming step 103, a bonding step 104, a grinding step 105, a dividing step 106, and a separating step 107.

### Oxide Film Forming Step

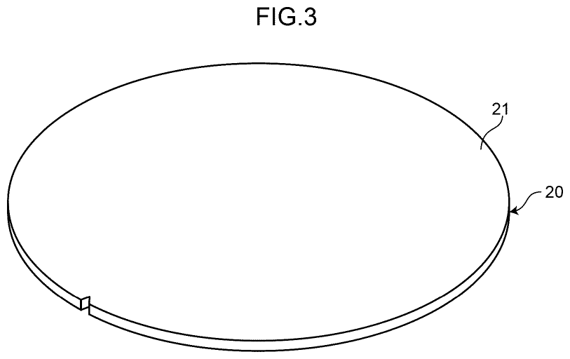

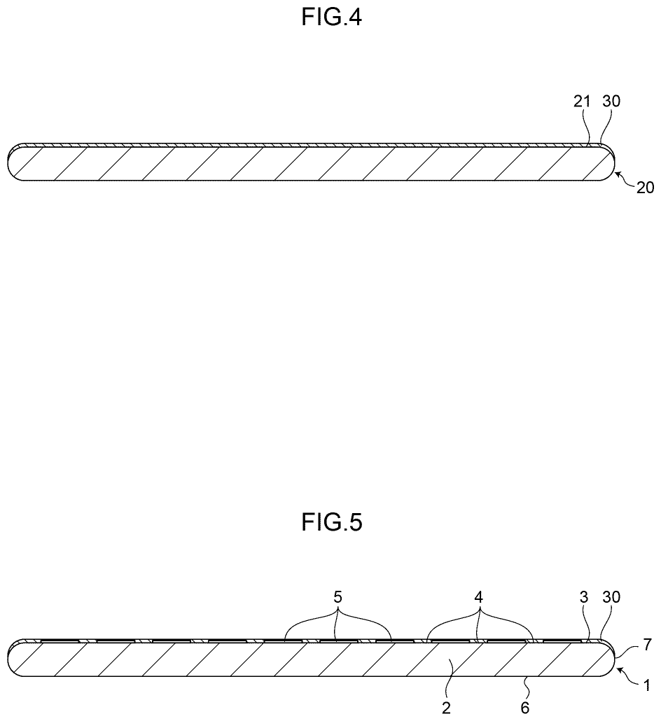

FIG. 3 is a perspective view schematically illustrating a carrier plate to be subjected to a hydrophilic treatment in the oxide film forming step of the manufacturing method illustrated in FIG. 2. FIG. 4 is a cross-sectional view schematically illustrating a carrier plate that has been subjected to a hydrophilic treatment in the oxide film forming step of the manufacturing method illustrated in FIG. 2. FIG. 5 is a cross-sectional view schematically illustrating a device wafer that has been subjected to a hydrophilic treatment in the oxide film forming step of the manufacturing method illustrated in FIG. 2.

The oxide film forming step 101 is a step of forming a moisture-containing oxide film 30 (illustrated in FIGS. 4 and 5) on at least one of the front surface 3 of the device wafer 1 and the front surface 3 of the carrier plate 20 illustrated in FIG. 3, which is a surface to be bonded to the device wafer 1, before performing the bonding step 104. In the first embodiment, the carrier plate 20 to be bonded to the device wafer 1 in the oxide film forming step 101 is, for example, a disk-shaped bare silicon wafer that is made of silicon, has the same diameter as the device wafer 1, and has no devices 5 formed thereon.

However, in the present disclosure, the carrier plate 20 may be a glass wafer made of glass or the like. In the present disclosure, the carrier plate 20 may be a wafer coated with an insulating film. In particular, in the case where the insulating film is made of an inorganic material such as an oxide film, a nitride film, a SiC film or the like, the insulating film is harder than an insulating film made of an organic material, so that the occurrence of chipping can be suppressed.

In the first embodiment, in the oxide film forming step 101, the moisture-containing oxide film 30 illustrated in FIGS. 4 and 5 is formed on the entire front surface 3 of the device wafer 1 and the entire one surface 21 of the carrier plate 20 to be bonded to the device wafer 1. The moisture-containing oxide film 30 is, for example, a silicon oxide film formed by using plasma enhanced chemical vapor deposition (PECVD).

The moisture-containing oxide film 30 is formed, for example, by supplying a gas obtained by vaporizing a liquid raw material such as liquid tetraethyl orthosilicate (TEOS) to a chamber in which the front surface 3 of the device wafer 1 and the one surface 21 of the carrier plate 20 are exposed in an internal space, and converting the gas into plasma.

Here, the temperature of the atmosphere at the time of forming the moisture-containing oxide film 30, that is, the temperature in the chamber is set so that the content of water in the formed moisture-containing oxide film 30 increases. For example, this temperature is set to be included in a first temperature range of 80° C. or more and 300° C. or less, preferably 100° C. or more and 260° C. or less, more preferably 120° C. or more and 220° C. or less, and most preferably 120° C. or more and 180° C. or less.

In addition, the moisture-containing oxide film 30 has a thin film thickness so as to prevent the device chip 10 from sinking into the carrier plate 20 side when the device chip 10 is bonded to the carrier plate 20. For example, the moisture-containing oxide film 30 has a film thickness of 1 μm or less, preferably 500 nm or less, more preferably 250 nm or less, and most preferably 125 nm or less.

In addition, in order to flatten the exposed surface of the moisture-containing oxide film 30, that is, the surface on the side far from the front surface 3 and the one surface 21 described above, a flattening treatment such as chemical mechanical polishing (CMP) may be performed on the exposed surface of the moisture-containing oxide film 30. Further, the moisture-containing oxide film 30 may be formed to have a film thickness of more than 1 μm, and then subjected to a flattening treatment to have a film thickness of 1 μm or less and to have the exposed surface flattened.

Note that, in the first embodiment, the moisture-containing oxide film 30 is formed on both the front surface 3 of the device wafer 1 and the one surface 21 of the carrier plate 20, but in the present disclosure, the moisture-containing oxide film 30 may be formed on at least one of the front surface 3 of the device wafer 1 and the one surface 21 of the carrier plate 20.

Further, in the present disclosure, the oxide film formed on at least one of the front surface 3 of the device wafer 1 and the one surface 21 of the carrier plate 20 in the oxide film forming step 101 may be an oxide film having a surface roughness roughened to such an extent that the oxide film can be peeled off in the subsequent separating step 107. Specifically, for example, the oxide film has an arithmetic average roughness (Ra), which is the surface roughness of the surface thereof, that is 1 nm or more and 3 nm or less.

### Hydrophilizing Step

The hydrophilizing step 102 is a step of subjecting the front surface 3 of the device wafer 1 and the one surface 21 of the carrier plate 20 to be bonded to the device wafer 1 to a hydrophilic treatment before performing the bonding step 104. In the first embodiment, a treatment for forming an OH group on the exposed surface of the moisture-containing oxide film 30 to activate the surface is performed in the hydrophilizing step 102.

In the first embodiment, the moisture-containing oxide film 30 on the front surface 3 of the device wafer 1 and the moisture-containing oxide film 30 on the one surface 21 of the carrier plate 20 are subjected to a hydrophilic treatment in the hydrophilizing step 102 by irradiating the exposed surface of the moisture-containing oxide film 30 with nitrogen plasma or ultraviolet rays under atmospheric pressure, for example.

Note that, in the first embodiment, when the hydrophilic treatment is performed in the hydrophilizing step 102, it is preferable that the water contained in the moisture-containing oxide film 30 is not vaporized. Therefore, it is desirable that the temperature of the atmosphere when the hydrophilic treatment is performed is set to a temperature lower than the temperature of the atmosphere when the moisture-containing oxide film 30 is formed, for example, room temperature.

### Trimming Step

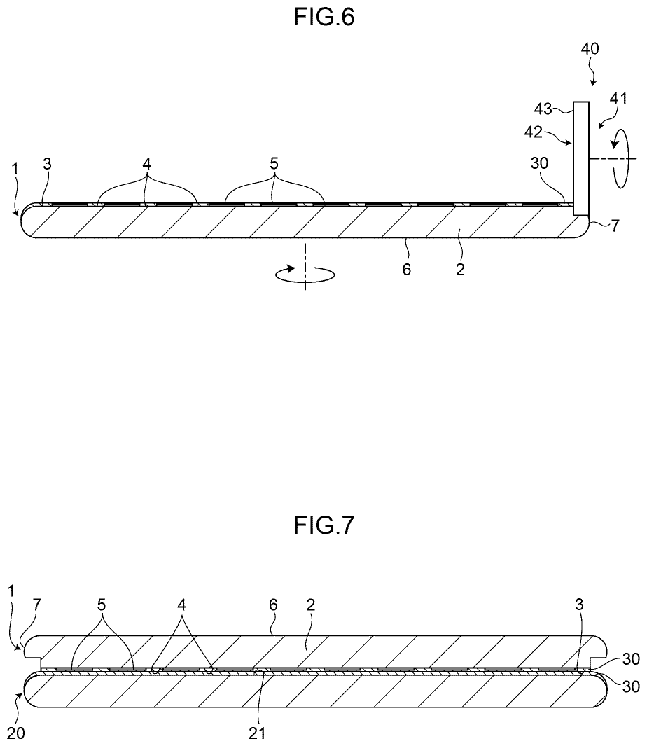

FIG. 6 is a side view schematically illustrating, partly in cross section, the trimming step of the manufacturing method illustrated in FIG. 2. The trimming step 103 is a step of removing the front surface side of the chamfered portion 7 of the device wafer 1.

In the first embodiment, a cutting apparatus 40 illustrated in FIG. 6 suction-holds the back surface 6 of the device wafer 1 on a holding surface of a holding table not illustrated, in the trimming step 103. In the first embodiment, as illustrated in FIG. 6, an annular cutting edge 43 of the cutting blade 42 rotated about the axis parallel to the holding surface by a spindle of a cutting unit 41 is caused by the cutting apparatus 40 to cut into the chamfered portion 7 from the front surface 3 side of the device wafer 1 until the annular cutting edge reaches the center in the thickness direction of the device wafer in the trimming step 103, thereby rotating the holding table at least once about the axis orthogonal to the holding surface.

In the first embodiment, as illustrated in FIG. 4, the cutting edge 43 of the cutting blade 42 is caused to cut into the chamfered portion 7 from the front surface 3 side to a depth greater than or equal to the finished thickness of the device chip 10 in the trimming step 103, thereby removing the front surface 3 side of the chamfered portion 7 over the entire circumference. In the first embodiment, the trimming step 103 is performed in order to prevent a sharp edge from being formed at the outer edge of the device wafer 1 after the grinding step 105. Note that, in the present disclosure, the trimming step 103 may not be performed.

### Bonding Step

FIG. 7 is a cross-sectional view schematically illustrating the device wafer and the like after the bonding step of the manufacturing method illustrated in FIG. 2. The bonding step 104 is a step of directly bonding the carrier plate 20 to the front surface 3 of the device wafer 1 without using an adhesive.

In the first embodiment, the moisture-containing oxide film 30 on the front surface 3 of the device wafer 1 and the moisture-containing oxide film 30 on the one surface 21 of each of the plurality of device chips 10 of the carrier plate 20 are first opposed to each other in the bonding step 104. In the first embodiment, the device wafer 1 and the carrier plate 20 are brought close to each other until, for example, a load of about 10 kN acts on the device wafer and the carrier plate in the bonding step 104.

In the first embodiment, as illustrated in FIG. 7, the moisture-containing oxide film 30 on the front surface 3 of the device wafer 1 and the moisture-containing oxide film 30 on the one surface 21 of the carrier plate 20 overlap each other in the bonding step 104, and hydrogen bonding occurs between these moisture-containing oxide films 30, whereby the front surface 3 of the device wafer 1 and the one surface 21 of the carrier plate 20 are bonded to each other via the moisture-containing oxide films 30.

Note that, in the first embodiment, the front surface 3 of the device wafer 1 and the one surface 21 of the carrier plate 20 may be bonded to each other under atmospheric pressure or under a reduced pressure atmosphere lower than or equal to 105 Pa (absolute pressure) in the bonding step 104. Further, in the first embodiment, water may be supplied to the exposed surface of the moisture-containing oxide films 30 immediately before bonding in order to promote hydrogen bonding occurring between the moisture-containing oxide films 30 in the bonding step 104.

Further, in the first embodiment, it is preferable that the water contained in the moisture-containing oxide films 30 is not vaporized in the bonding step 104. Therefore, in the first embodiment, the temperature of the atmosphere when the bonding is performed may be set to a temperature lower than the temperature of the atmosphere when the moisture-containing oxide film 30 is formed, for example, room temperature, in the bonding step 104. Further, in the present disclosure, an annealing treatment may be performed after the device wafer 1 and the carrier plate 20 are bonded in the bonding step 104, and in this case, it is desirable to perform the annealing treatment, for example, at about 150° C. or more and 200° C. or less for about 2 hours.

### Grinding Step

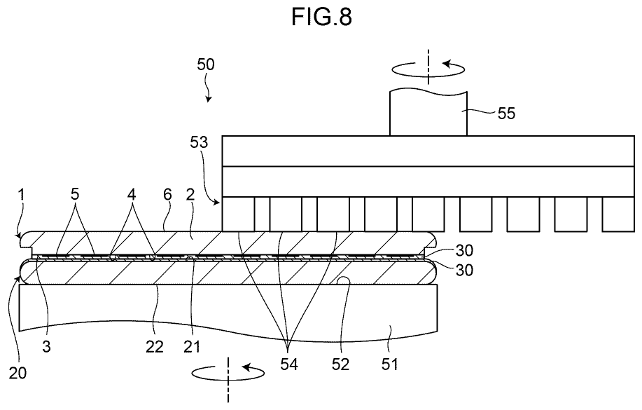

FIG. 8 is a side view schematically illustrating, partly in cross section, the grinding step of the manufacturing method illustrated in FIG. 2. The grinding step 105 is a step of grinding the back surface 6 of the device wafer 1 after performing the bonding step 104.

In the first embodiment, a grinding apparatus 50 illustrated in FIG. 8 suction-holds the other surface 22 side of the carrier plate 20, which is the back side of the one surface 21 of the carrier plate 20, on a holding surface 52 of a holding table 51, in the grinding step 105. In the first embodiment, as illustrated in FIG. 8, the grinding apparatus 50 supplies grinding fluid while rotating a grinding wheel 53 about the axis thereof by a spindle 55 and rotating the holding table 51 about the axis thereof, and brings grindstone 54 into contact with the back surface 6 of the device wafer 1 and brings the grindstone close to the holding table 51 at a predetermined feed speed in the grinding step 105, thereby grinding the back surface 6 of the device wafer 1 with the grindstone 54 to thin the device wafer 1 to a finished thickness of the device chip 10. After the grinding step 105, in the device wafer 1, the chamfered portion 7 is removed over the entire circumference.

### Dividing Step

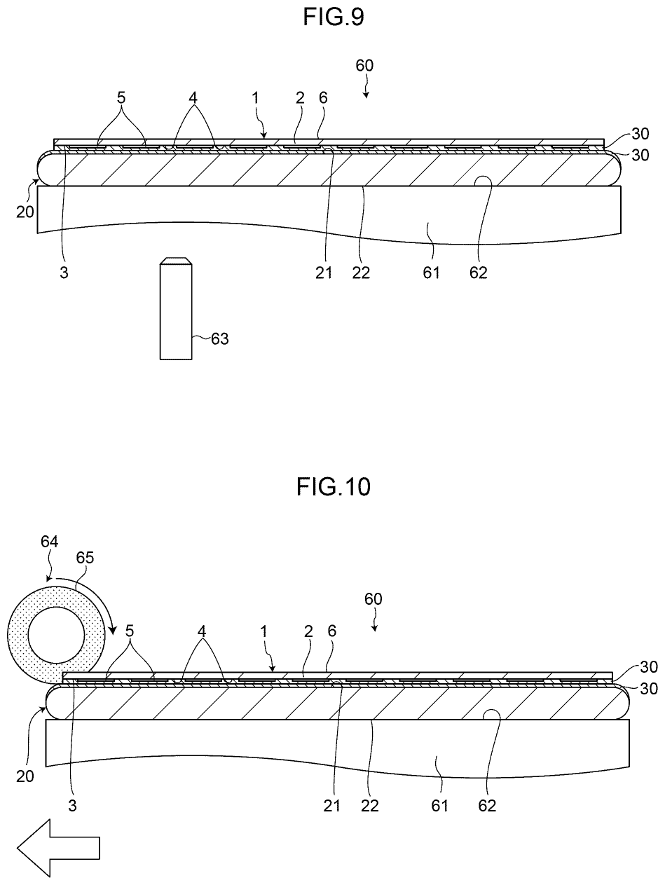

FIG. 9 is a side view schematically illustrating, partly in cross section, a state in which the device wafer held on the chuck table is imaged in the dividing step of the manufacturing method illustrated in FIG. 2. FIG. 10 is a side view schematically illustrating, partly in cross section, a state in which the device wafer is cut in the dividing step of the manufacturing method illustrated in FIG. 2.

The dividing step 106 is a step of dicing the device wafer 1 supported by the carrier plate 20 along the planned dividing lines 4 after the bonding step 104 to thereby form a plurality of device chips 10. In the first embodiment, a cutting apparatus 60 illustrated in FIGS. 9 and 10 suction-holds the other surface 22 of the carrier plate 20 on a holding surface 62 of a holding table 61 composed of a material that transmits infrared rays, in the dividing step 106.

In the first embodiment, the cutting apparatus 60 images, as illustrated in FIG. 9, the front surface 3 side of the device wafer 1 with an infrared camera 63 through the holding table 61 and the carrier plate 20 in the dividing step 106, and performs alignment to align the planned dividing lines 4 of the device wafer 1 with a cutting edge 65 of a cutting blade 64 illustrated in FIG. 10. In the first embodiment, as illustrated in FIG. 10, the cutting edge 65 of the cutting blade 64 is caused by the cutting apparatus 60 to cut into the device wafer 1 along the planned dividing lines 4 until the cutting edge reaches the carrier plate 20 while moving the cutting edge 65 of the cutting blade 64 and the device wafer 1 relative to each other along the planned dividing lines 4 in the dividing step 106, thereby cutting the device wafer 1.

In the first embodiment, the cutting edge 65 of the cutting blade 64 is caused by the cutting apparatus 60 to cut into the device wafer along the planned dividing lines 4 until the cutting edge reaches the carrier plate 20 in the dividing step 106, thereby cutting the device wafer 1 along all the planned dividing lines 4 to divide the device wafer 1 into individual device chips 10. Thus, in the first embodiment, the device wafer 1 is cut by the cutting blade 64 while the cutting blade 64 is caused to cut into the device wafer from the device wafer 1 side to a depth reaching the carrier plate 20 in the dividing step 106, thereby dividing the device wafer 1 bonded to the carrier plate 20 into a plurality of device chips 10.

Note that, in the present disclosure, the device wafer 1 may be imaged by the infrared camera 63 from the back surface 6 side of the device wafer 1 in the dividing step 106 to perform alignment. Further, in the present disclosure, the dividing step 106 is not limited to cutting by using the cutting blade 64, but the device wafer 1 may be divided into a plurality of device chips 10 by plasma etching along the planned dividing lines 4, or may be divided into a plurality of device chips 10 by irradiating a laser beam along the planned dividing lines 4, for example.

### Separating Step

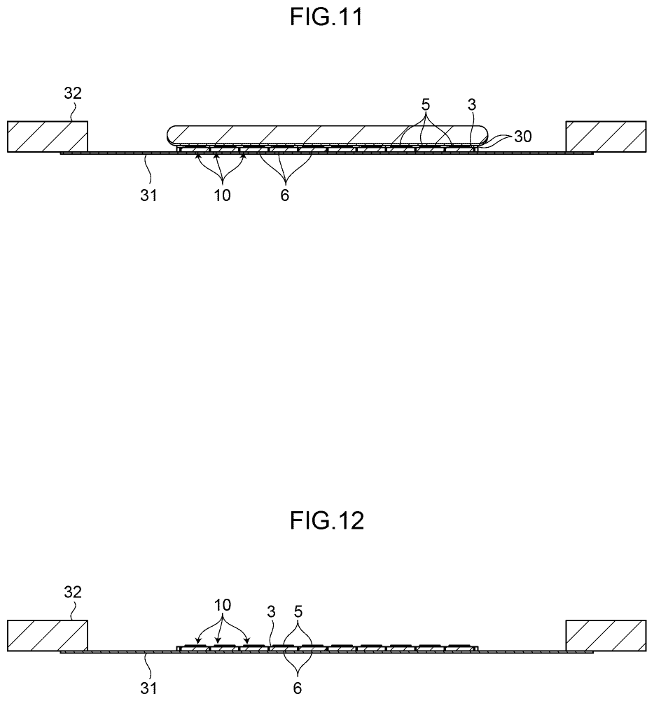

FIG. 11 is a cross-sectional view schematically illustrating a state in which a dicing tape is attached to back surfaces of a plurality of device chips in the separating step of the manufacturing method illustrated in FIG. 2. FIG. 12 is a cross-sectional view schematically illustrating a state in which a carrier wafer is separated from front surfaces of the device chips in the separating step of the manufacturing method illustrated in FIG. 2.

The separating step 107 is a step of separating the plurality of device chips 10 from the carrier plate 20 after performing the dividing step 106. In the embodiment, as illustrated in FIG. 11, a central portion of a disk-shaped dicing tape 31 having a diameter larger than the outer diameter of the device wafer 1 is attached to the back surfaces 6 of the plurality of device chips 10 bonded to the carrier plate 20, and an annular frame 32 having an inner diameter larger than the device wafer 1 is attached to an outer edge portion of the dicing tape 31, in the separating step 107.

In the first embodiment, the plurality of device chips 10 bonded to the carrier plate 20 is heated under a nitrogen atmosphere by using a heat treatment apparatus including an infrared lamp, for example, in the separating step 107. Thus, in the first embodiment, the water contained in the moisture-containing oxide film 30 is vaporized to generate a gas in the moisture-containing oxide film 30 in the separating step 107, thereby separating the carrier plate 20 from the plurality of device chips 10 as illustrated in FIG. 12.

Note that, in order to vaporize the water contained in the moisture-containing oxide film 30, the temperature of the atmosphere needs to be higher than that when the moisture-containing oxide film 30 is formed. On the other hand, if the temperature of the atmosphere at the time of heating the plurality of device chips 10 bonded to the carrier plate 20 is too high, siloxane bonding stronger than hydrogen bonding may occur between the moisture-containing oxide films 30.

Therefore, in the first embodiment, the temperature of the atmosphere when heating the plurality of device chips 10 bonded to the carrier plate 20 is set to be included in a second temperature range of 200° C. or more and 350° C. or less, preferably 215° C. or more and 320° C. or less, more preferably 230° C. or more and 290° C. or less, and most preferably 245° C. or more and 260° C. or less in the separating step 107.

Further, in the present disclosure, when the carrier plate 20 and the device wafer 1 are bonded to each other without forming the moisture-containing oxide film 30 in the separating step 107, a blade may be inserted between the carrier plate 20 and the device chip 10 to form a starting point of peeling, and the carrier plate 20 and the device chip 10 may be physically peeled from each other.

In the manufacturing method according to the first embodiment described above, since the device 5 is protected by directly bonding the carrier plate 20 to the device wafer 1, there is an effect that a residue of an adhesive on the device 5 of the device chip 10 after the division can be suppressed.

Further, in the manufacturing method according to the first embodiment, since the carrier plate 20 is bonded to the front surface 3 of the device wafer 1, and the device wafer is cut in a state of being supported by the carrier plate 20, there is no possibility that a burr is generated even if a metal such as TEG is present in a region to be cut.

Further, in the manufacturing method according to the first embodiment, since the interlayer insulating film constituting the device 5 is cut in a state of being sandwiched between the base material 2 of the device wafer 1 and the carrier plate 20, there is no possibility that peeling called delamination occurs.

Further, in the manufacturing method according to the first embodiment, since the grinding step 105 is performed before the dividing step 106, grinding is performed before dicing rather than performing the grinding step 105 after the dividing step 106, so that there is an effect that grinding waste does not enter the grooves formed in the dividing step 106. In addition, in the manufacturing method according to the first embodiment, since the grinding step 105 is performed before the dividing step 106, grinding is performed before dicing rather than performing the grinding step 105 after the dividing step 106, so that the depth of the grooves formed in the dividing step 106 can be made shallow, and the dicing quality and the unit per hour (UPH) are increased at the time of the dividing step 106 (In the case of plasma etching, the etching time can be reduced, and in the case of cutting with the cutting blade 64, processing can be performed with the cutting blade 64 made of a material having a fine particle size).

According to the present disclosure, it is possible to suppress a residue of an adhesive.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A method of manufacturing a plurality of devices by dividing a device wafer along a plurality of planned dividing lines intersecting each other, the device wafer having a device surface on which each of the devices is formed in each of regions partitioned by the planned dividing lines, the method comprising:
directly bonding a carrier plate to the device surface of the device wafer;
after the bonding of the carrier plate, dicing the device wafer supported by the carrier plate along the planned dividing lines to thereby form a plurality of devices; and
after the forming of the plurality of devices, separating the plurality of devices from the carrier plate.

2. The method according to claim 1, wherein the dicing of the device wafer includes cutting the device wafer to be divided by a cutting blade while causing the cutting blade to cut into the device wafer from the device wafer side to a depth reaching the carrier plate.

3. The method according to claim 1, further comprising, after the bonding of the carrier plate, grinding a back surface of the device wafer.

4. The method according to claim 1, further comprising, before the bonding of the carrier plate, performing hydrophilic treatment on each of the device surface of the device wafer and a surface of a carrier plate to be bonded to the device wafer.

5. The method according to claim 1, further comprising, before the bonding of the carrier plate, forming a moisture-containing oxide film on at least one of the device surface of the device wafer and a surface of a carrier plate to be bonded to the device wafer,
wherein the separating of the plurality of devices includes separating the plurality of devices from the carrier plate by heating.
